(19) United States
(12) Patent Application Publication
(10) Pub. No.: US 2026/0231708 A1
(43) Pub. Date: Aug. 6, 2026

(54) METHOD FOR MANUFACTURING MICROSTRUCTURES

(71) Applicant: COMMISSARIAT A L'ENERGIE ATOMIQUE ET AUX ENERGIES ALTERNATIVES, Paris (FR)

(72) Inventors: Quentin ABADIE, Grenoble Cedex 09 (FR); Nicolas MICHIT, Grenoble Cedex 09 (FR); Carole PERNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/461,865

(22) Filed: Jan. 28, 2026

(30) Foreign Application Priority Data
Jan. 31, 2025 (FR) FR2501017

(51) Int. Cl. H10P 50/61; G02B 5/18; H10D 8/01; H10D 62/83; H10D 62/85; H10D 62/852; H10P 50/00

(52) U.S. Cl. CPC H10P 50/613; G02B 5/1857; H10D 8/01; H10D 62/83; H10D 62/85; H10D 62/8503; H10D 62/852; H10P 50/617; H10P 50/695

(57) ABSTRACT

A method for manufacturing microstructures includes providing a substrate having an upper face extending parallel to a main plane. The substrate is anisotropically etched from the upper face to form at least one pad having a first surface projected onto the main plane. The at least one pad is then electro-etched to form a pillar having a second surface projected onto the main plane that is smaller than the first surface.

### TECHNICAL FIELD

The present invention relates to the field of electronics, for example, microelectronics or optoelectronics. The invention relates, quite specifically, to a method for manufacturing microstructures. The present invention has advantageous applications in various fields, like for example, those of integrated micro-optics and optical metasurfaces.

### PRIOR ART

Very many technical fields today use small structures, typically around one hundred or a few hundred nanometres. Such structures are, for example, used in integrated micro-optics or to produce metasurfaces having innovative optical properties.

Developments in these fields are, however, restricted by current technological limits to form smaller structures. Photolithography and etching steps are particularly limiting during the manufacture of structures. Indeed, it is complex, with currently existing equipment and resins used during photolithography steps, to precisely form structures having very small dimensions, typically dimensions less than 100 nm. Such dimensions can only be obtained today by means of long methods which are difficult to industrialise, like e-beam lithography, or by using advanced lithography equipment, like immersion lithography equipment, very expensive and available only for substrates which are 300 mm in diameter.

There is therefore a need to push back against the currently existing barriers in forming very small structures. Preferably, the invention will propose a solution for forming structures having characteristic dimensions less than 100 nm. Preferably, the invention will propose a solution adapted to methods which are not compatible with immersion lithography, and in particular, a solution which is compatible with substrates which are 200 mm in diameter. Preferably, the invention will propose a low-cost solution.

### SUMMARY

To achieve this aim, a first aspect of the invention relates to a method for manufacturing microstructures comprising the following steps:
providing a substrate, the substrate having an upper face extending mainly parallel to a plane called main plane,
performing an anisotropic etching of the substrate from its upper face and along a vertical direction (Z) perpendicular to the main plane, so as to form at least one pad in the substrate, the pad having, projecting into the main plane, a first surface S₁₀₀ and a height H₁₀₀ along the vertical direction,
performing an electro-etching of the at least one pad so as to form a pillar, the pillar having, projecting into the main plane, a second surface S₁₀₀₀, with S₁₀₀₀<S₁₀₀ and a height along the vertical direction equal to H₁₀₀.

By implementing an electro-etching step after the etching step, it is possible to reach dimensions which can be difficult to be, even cannot be, obtained using current etching equipment.

It must be noted that the microelectronic etching methods do not usually serve to define the dimensions of a final object. They are rather intended to structure patterned layers which do not form the final structures of the method. The present invention therefore resorts to etching with an unusual aim.

Thus, the present invention resorts to two material removal techniques coming from two different technical fields to push back against the currently existing barriers in forming very small structures. While recent etching equipment has dimensional limits of a few hundred nanometres, or, for the most advanced, of around 100 nm—sometimes 70 to 80 nm for very advanced equipment which is only accessible to 300 mm technologies—the method according to the invention makes it possible to form structures having characteristic dimensions less than 100 nm, typically around a few tens of nanometres, for example, going up to 10 nm. The method according to the invention makes it possible to reach these dimensions, both for 300 mm and 200 mm technologies.

Moreover, the method according to the invention can be used to produce pillars with varied geometries. Indeed, the electro-etching step is only very slightly, even not limiting regarding defining the shape of the pillars.

Another advantage of the method according to the present invention is that it is possible to utilise doping differences to simultaneously create structures of different sizes, that it is sought to manufacture structures of dimensions, all less than 100 nm or some less and some greater than 100 nm. Structures of varied shapes and dimensions can thus coexist on the substrate at the end of the method.

The invention is distinguished, in particular, from solutions proposed in the prior art for producing silicon microrod arrays provided with nanotips. An example is described by Yaghootkar Bahareh et al in the article, “Promising method toward realization of ultra-low-cost silicon microrod array with nanotip”, JOURNAL OF VACUUM SCIENCE, 2020. It is proposed in this document to produce a pyramid structure texturisation of the surface of a substrate, then to produce an electrochemical etching to deepen between the pyramid structures and thus form vertical microrods, the height of which is tip-shaped. In this solution, the texturisation step only etches the substrate over a shallow depth, and it is the electrochemical etching which mainly defines the vertical dimension of the microrods. Electrochemical etching moreover serves in this solution to define the lateral dimensions of the microrods. This dual function of electrochemical etching induces a poor control of the dimensions of the microrods, as it is complex, even impossible during one same etching step to simultaneously, precisely reach the desired height and the desired lateral dimensions for microrods. In the scope of the present invention, the anisotropic etching makes it possible to give a precise height to each pillar, which will also substantially be the height of the pillars. Electro-etching itself makes it possible to reduce the lateral dimensions of the pads until arriving precisely at the desired lateral dimensions for the pillars.

Moreover, in this article of the prior art, during the texturization of the surface of the substrate in the form of pyramid structures, the height of the latter depends on the crystalline planes of the etched material. This again induces an uncertainty and a lack of control over the final height of the microrods.

Furthermore, the pyramid apex of the tips can have a negative optical effect, both on the subsequent etching step and more generally, in the targeted applications. This solution of the prior art is therefore not applicable for all the applications. In the method according to the invention, the apexes of the pads are flat and their vertical flanks, which is more advantageous.

Finally, it is complex in the scope of this solution of the prior art to produce pillars of different dimensions side by side. This is permitted and facilitated by the method according to the invention.

A second aspect of the invention relates to a method for manufacturing a microelectronic component implementing the method according to the first aspect of the invention, in which the pillar is intended to form a diode.

A third aspect of the invention relates to a method for manufacturing a microelectronic component implementing the method according to the first aspect of the invention, in which the pillar is intended to form an optical element taken from among: an extraction structure, an optical metasurface, a photonic crystal, diffractive element.

The advantages provided by the method according to the first aspect of the invention apply mutatis mutandis to the method according to the second and third aspects of the invention.

### BRIEF DESCRIPTION OF THE FIGURES

The aims, objectives, as well as the features and advantages of the invention will best emerge from the detailed description of an embodiment of the latter which is illustrated by the following accompanying drawings, in which:

FIGS. 1A to 1E illustrate the steps of an embodiment according to the method according to the invention.

FIGS. 2A to 2C illustrate different geometries being able to be implemented for the pillar obtained at the end of the method according to the invention.

FIG. 3 is a schematic graph illustrating the three operating regions when a study material is immersed in an electrolytic solution and that a potential is imposed between this material and a counterelectrode.

FIGS. 4A and 4B illustrate an embodiment in which pads are doped according to distinct rates, enabling the formation of pillar at distinct characteristic dimensions.

FIGS. 5A and 5B are results of simulations illustrating the transmission and the phase shift of a metasurface as a function of the diameter of the structures forming it.

FIGS. 6A to 6C illustrate an embodiment in which a hard mask is deposited on the substrate and in which pad lateral dimensions are given to this hard mask and they are made to be preserved during the transformation of the pad into pillar.

The drawings are given as examples and are not limiting of the invention. They constitute principle schematic representations intended to facilitate the understanding of the invention and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to a preferred example, S₁₀₀₀≤0.75*S₁₀₀, preferably S₁₀₀₀≤0.5*S₁₀₀, preferably S₁₀₀₀≤0.25*S₁₀₀. Preferably, in all the planes parallel to the main plane and passing through the pad then through the pillar, S₁₀₀₀<S₁₀₀, preferably S₁₀₀₀≤0.75*S₁₀₀, preferably S₁₀₀₀≤0.5*S₁₀₀, preferably S₁₀₀₀≤0.25*S₁₀₀.

According to a preferred example, the at least one pad has, projecting into the main plane, a characteristic dimension L₁₀₀ with L100≥80 nm, preferably L100≥100nm.

According to a preferred example, L₁₀₀≤1 μm.

According to a preferred example, the at least one pillar has, projecting into the main plane, a characteristic dimension L₁₀₀₀ with L₁₀₀₀≤50 nm, preferably L₁₀₀₀≤30 nm.

According to a preferred example, projecting into the main plane, the at least one pad has a characteristic dimension L₁₀₀ and the at least one pillar, a characteristic dimension L₁₀₀₀, with L₁₀₀₀≤0.75*L₁₀₀, preferably L₁₀₀₀≤0.5*L₁₀₀, preferably L₁₀₀₀≤0.25*L₁₀₀. Preferably, in all the planes parallel to the main plane, and passing through the pad then through the pillar, L₁₀₀₀≤0.75*L₁₀₀, preferably L₁₀₀₀≤0.5*L₁₀₀, preferably L₁₀₀₀≤0.25*L₁₀₀.

According to a preferred example, the substrate is doped according to a non-uniform doping and the etching of the substrate is configured to form a plurality of pads in the substrate, at least one first pad and one second pad of the plurality of pads being formed in regions of the substrate having distinct dopings, such that the step of electro-etching the first pad and the second pad results in the formation of a first pillar and of a second pillar respectively having, projecting into the main plane, a second surface S_{1000,a} and S_{1000,b} such that S_{1000,a}≠S_{1000,b}. Preferably, after the etching step and before the electro-etching step, the pads have distinct surfaces S₁₀₀ₐ, S_{100b}.

According to a preferred example, the substrate has a non-doped region and a doped region, optionally in a non-uniform manner, and the etching of the substrate is configured to form a plurality of pads in the substrate, at least one first pad of the plurality of pads being formed in the non-doped region and at least one second pad of the plurality of pads being formed in the doped region. The electro-etching will thus be effective on the second pad, but not at the first pad. The first pad will therefore remain intact after the electro-etching step. In this example, therefore S₁₀₀ₐ=S₁₀₀₀ₐ and S₁₀₀₀ₐ≠S_{1000b}. Preferably, after the etching step and before the electro-etching step, the pads have equal surfaces S₁₀₀ₐ, S_{100b}.

According to a preferred example, the etching step comprises:
the production of a mask on the upper face of the substrate, the mask comprising openings,
   the electro-etching step being carried out in the presence of the mask.

According to a preferred example, the etching step comprises:
the production of a mask on the upper face of the substrate, the mask (20) comprising openings,
   the electro-etching step being carried out after a step of removing the mask.

According to an example, the etching step further comprises, before the production of the mask, a production of a hard mask on the upper face of the substrate, the mask then being deposited on the hard mask. The anisotropic etching is configured to etch the hard mask and give it a surface, projecting into the main plane, equal to the first surface S₁₀₀, and the hard mask is configured to preserve its surface equal to S₁₀₀ during the electro-etching.

According to a preferred example, the substrate is with the basis of a semiconductor material, for example, chosen from among the following materials: Ge, Si, InP, GaN, InGaN, AlGaN.

It is specified that, in the scope of the present invention, the terms “on”, “surmounts”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only or this material M, and optionally of other materials, for example, alloy elements, impurities or doping elements.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA:B.

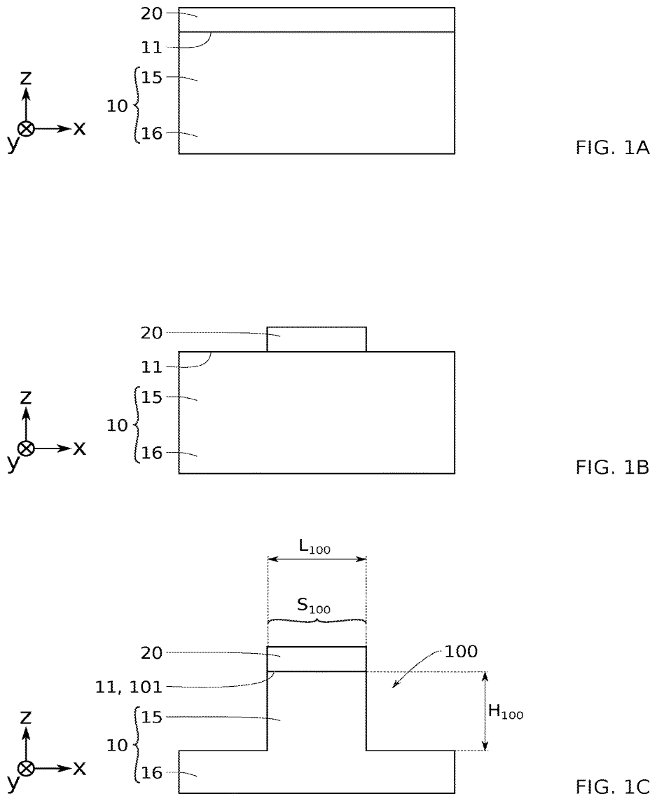

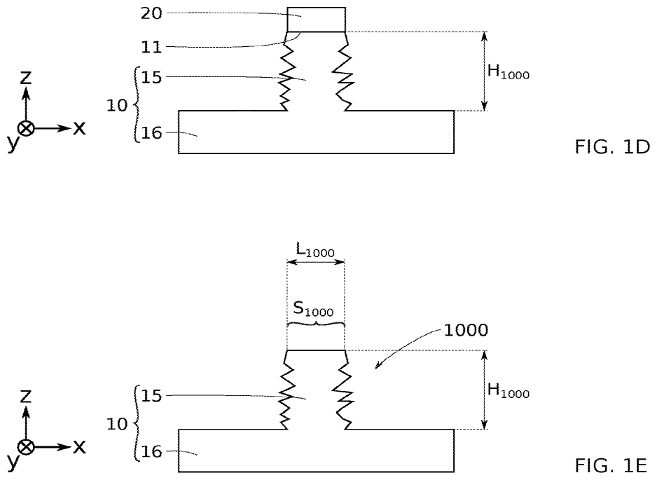

A preferably orthonormal system, comprising the axes X, Y, Z is represented in figure 1A.

In the present patent application, preferably thickness will be referred to for a layer, and height will be referred to for a structure or a device. The height is taken perpendicularly to the main plane XY. The thickness is taken along a direction normal to the main extension plane of the layer. Thus, a layer typically has a thickness along Z, when it extends mainly along the main plane XY, and a projecting element, for example, an isolation trench, has a height along Z. The relative terms “on”, “under”, “above”, “below”, preferably refer to positions taken along the direction Z.

The terms “substantially”, “around”, “about” mean “plus or minus 10%, preferably 5%”.

The method according to the invention will now be described in detail in reference to FIGS. 1A to 1D.

A first step of the method comprises the provision of a substrate 10 with the basis of a semiconductor material. This substrate 10 has an upper face 11 extending mainly parallel to a main plane XY. The main plane XY is defined by a first direction X and a second direction Y. The main plane XY is perpendicular to a third direction Z, also called vertical direction Z.

The substrate 10 is with the basis of a material enabling its etching by electro-etching. This material can, in particular, be a semiconductor, in particular a nitride or a phosphide. It can, for example, be chosen from among the following list: GaN, Ge, Si, InP, InGaN, AlGaN.

As mentioned in the introduction, one of the advantageous applications of the present invention is that of optical metasurfaces, for which the material must be structured at a scale less than the working wavelength and this, made of materials with a high refraction index and without absorption losses. In this scope, when the working wavelength is located in the infrared, materials of interest for the substrate 10 are silicon (Si) and germanium (Ge). When the working wavelength is located in the visible spectrum, a material of interest is GaN.

The substrate 10 can also be doped. This embodiment and its different variants will be described further.

A second step of the method according to the invention comprises an etching of the substrate 10 from its upper face 11. To do this, it is possible to use a conventional technique of depositing a mask 20, typically a resin layer 20, on the upper face 11 of the substrate 10 (FIG. 1A), forming a pattern in the resin 20 by a photolithography (FIG. 1B) then etching (FIG. 1C) method. The etching is typically an anisotropic etching along the vertical direction Z, perpendicular to the main plane XY.

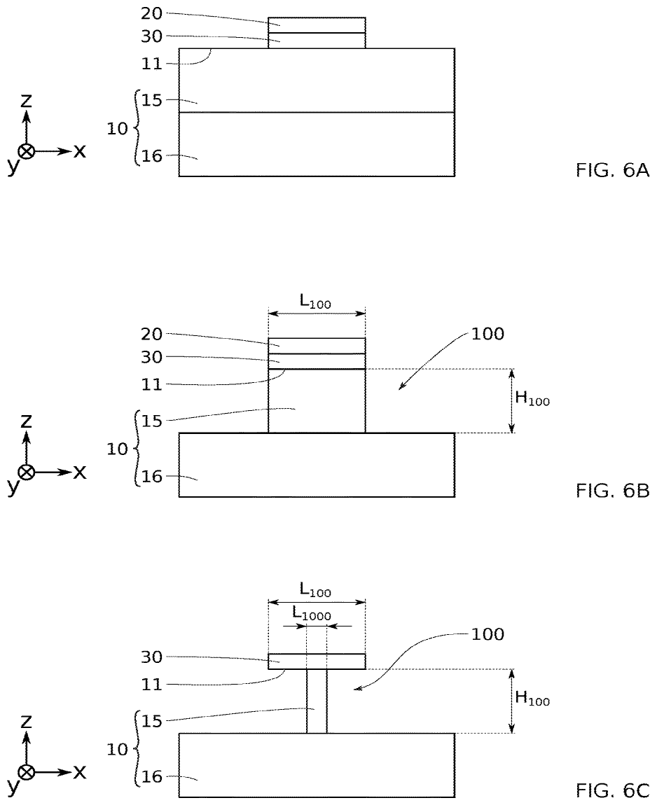

According to a particular embodiment, it is possible to deposit a hard mask 30 on the substrate 10, before the deposition of the resin layer 20. The hard mask 30 is thus inserted between the substrate 10 and the resin layer 20 and is protected by the resin layer 20. The hard mask 30 is advantageously with the basis of a material sensitive to anisotropic etching, but insensitive to electro-etching which will be described further. The hard mask 30 can, in particular, be SiO₂-based. FIG. 6A illustrates the assembly obtained after definition of the patterns in the resin layer 20 and in the hard mask 30, before the etching and the formation of the pad 100.

The etching step is configured to form a pad 100 in the substrate 10. The pad 100 has, projecting into the main plane XY, a first surface S₁₀₀. The pad 100 can be of various shapes. It can, for example, have a circular, hexagonal or rectangular, even square shape, projecting into the main plane XY. Preferably, the shape of the pad 100 is substantially constant along the third direction Z. Thus, as illustrated in FIG. 1C, the flanks of the pad 100 are preferably vertical, i.e. parallel to the vertical direction Z. This is, in particular, permitted by the anisotropic character of the etching.

Preferably, the pad 100 has an upper face 101 or flat apex 101, i.e. parallel to the main plane XY. Advantageously, the apex 101 of the pad 100 and its flanks form right angles. More generally, advantageously, the apex 101 of the pad 100 and the generating lines of its flanks form right angles. In other words, preferably, the apex 101 of the pad 100 is not inclined with respect to a plane parallel to the main plane XY and is, in particular, not pyramid-shaped.

The pad 100 has a height H₁₀₀ along the vertical direction Z. The desired value of the height H₁₀₀ is obtained by configuring the anisotropic etching. The height of the future pillar 1000 is substantially equal to H₁₀₀. Thus, the sizing of H₁₀₀ is done as a function of the desired height for the final pillar. The anisotropic etching thus defines the height of the pillar 1000.

The pad 100 has a characteristic dimension L₁₀₀ projecting into the main plane XY. This characteristic dimension L₁₀₀ typically corresponds to the maximum dimension of the pad 100 taken in a plane parallel to the main plane XY. When the pad 100 has a circular or substantially circular shape projecting into the plane XY, L₁₀₀ typically corresponds to the diameter of the pad in the plane XY. When the pad 100 has a rectangular shape projecting into the plane XY, L₁₀₀ typically corresponds to the longest side of this rectangle in the plane XY.

The characteristic dimension L₁₀₀ can only descend below the limits that offer current photolithography and etching techniques. These limits are, in particular, dependent on the equipment used and on the nature of the resin used for the photolithography step.

Thus, the characteristic dimension L₁₀₀ is typically around a few hundred nanometres. Advanced etching and photolithography equipment can make it possible that L₁₀₀ is around one hundred nanometres, even a little below (around up to 80 nm). Dimensions of around 10 nm or 50 nm cannot be considered.

FIG. 6B illustrates the assembly obtained after the formation of the pad 100 in the particular embodiment where a hard mask 30 has been inserted between the substrate 10 and the resin layer 20. At this stage, the hard mask 30 has the same characteristic dimension L₁₀₀ as the underlying pad 100.

A third step of the method according to the invention comprises an electro-etching of the pad 100. This electro-etching makes it possible to form a pillar 1000 (FIG. 1D).

The pillar 1000 has, projecting into the main plane XY, a second surface S₁₀₀₀. Through manufacture, the second surface S₁₀₀₀ is smaller than the first surface S₁₀₀. The electro-etching is thus configured to modify the lateral dimensions of the pad and carry it at the desired lateral dimensions for the pillar. The electro-etching is therefore mainly a lateral etching, i.e. acting perpendicularly to the flanks of the pad 100. In other words, the electro-etching mainly acts parallel to the main plane XY.

The pillar 1000 can be of various shapes. It can, for example, have a circular or rectangular, even square shape projecting into the main plane XY. Preferably, the shape of the pillar 1000 is substantially constant along the third direction Z.

The pillar 1000 has a characteristic dimension L₁₀₀₀ projecting into the main plane XY. This characteristic dimension L₁₀₀₀ typically corresponds to the maximum dimension of the pillar 1000 taken in a plane parallel to the main plane XY. When the pillar 1000 has a circular or substantially circular shape projecting into the plane XY, L₁₀₀₀ typically corresponds to the diameter of the pillar 1000 in the plane XY. When the pillar 1000 has a rectangular shape projecting into the plane XY, L₁₀₀₀ typically corresponds to the longest side of this rectangle in the plane XY.

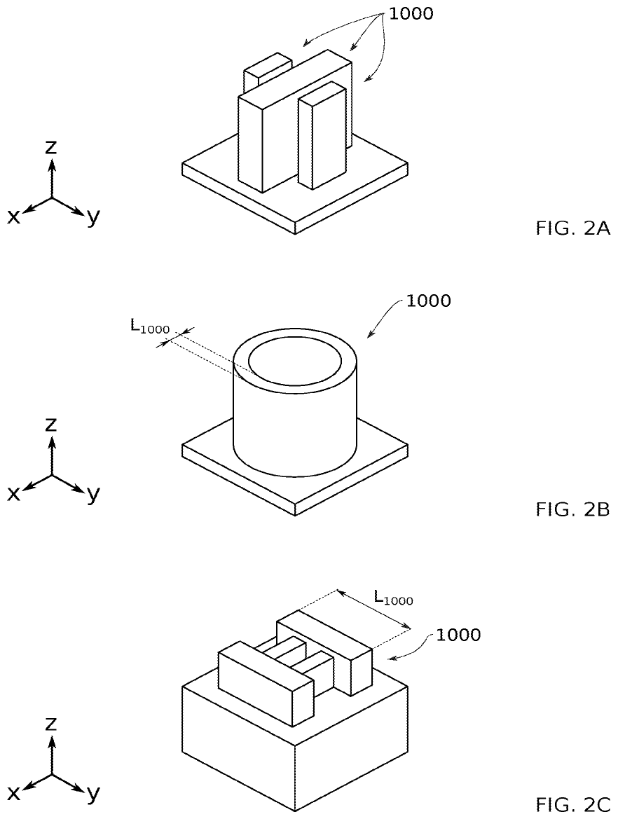

FIGS. 2A to 2C illustrate shapes being able to be taken by the pillar 1000 (or assemblies of pillars 1000). FIG. 2A, for example, illustrates three pillars 1000 each having a rectangular shape. FIG. 2B illustrates a pillar 1000 having, projecting into the main plane XY, a crown shape. The characteristic dimension L₁₀₀₀ of the pillar 1000 corresponds, in this case, to the difference between the outer radius and the inner radius of the crown. FIG. 2C illustrates a pillar 1000 having a complex shape. The pillar 100 has a generally “H” shape, two main walls being connected by two perpendicular walls of smaller dimensions. The characteristic dimension L₁₀₀₀ of the pillar 1000 corresponds, in this case, to the length of the main walls.

The pillars 1000 illustrated in FIGS. 2A, 2B and 2C are microstructures—or meta-atoms —being able to be used to create metasurfaces with various optical properties (filtering, focalisation, collimation, extraction, diffraction array, etc.).

It is understood that the examples of shapes for the pillar 1000 described above are given in a non-limiting manner. A geometry infinity can be considered and can be obtained by the method according to the invention.

The following paragraphs aim to describe the implementation of the electro-etching step.

This step can be carried out according to the following substeps:
electrically connecting the substrate 10 and a counterelectrode to a voltage or current generator,
immersing the substrate 10 and the counterelectrode in an electrolytic solution,
applying a voltage or a current between the substrate 10 and the counterelectrode so as to cause

The counterelectrode is made of an electrically conductive material, like for example, a metal such as platinum.

The electrodes are immersed in an electrolyte, also called electrolytic bath or electrolytic solution. The electrolyte can be acid or basic. The electrolyte is, for example, oxalic acid. This can also be KOH, HF, HNO₃, NaNO₃, H₂SO₄ or also an oxalic acid and NaNO₃ mixture.

The voltage applied is a function of the doping rate of the material and can go from 1 to 100V. It is applied, for example, for a duration going from a few milliseconds to several tens of minutes. The duration of applying the voltage or the current depends on the dimensions that are sought to be given to the pillar 1000 at the end of the method. The most it is sought that the second surface S₁₀₀₀ of the pillar 1000 is reduced, the greater the duration of application will be.

Preferably, the electro-etching step is applied uniformly on the substrate. The parameters of the electro-etching step, in particular, the voltage applied, are applied uniformly on the substrate.

The electro-etching step used in the method according to the present invention is differentiated from an electro-polishing step such as understood in the particular field of electrochemistry. The aim of electro-polishing is to make a surface as smooth as possible. In this type of method, a compound is deposited on the rough surface to be polished and is housed in the valleys defined by the surface roughness. This compound locally prevents, at the valleys, the electrochemical reaction. The peaks separating the valleys filled with the component are themselves etched by the electrochemical reaction. This enables a decrease of the roughness of the surface, and therefore leads to an almost smooth, even smooth surface. This method differs completely from the electro-etching step used in the present invention. The aim of the electro-etching step in the present invention is to reduce the dimensions of the pad 100 to arrive at the pillar 1000.

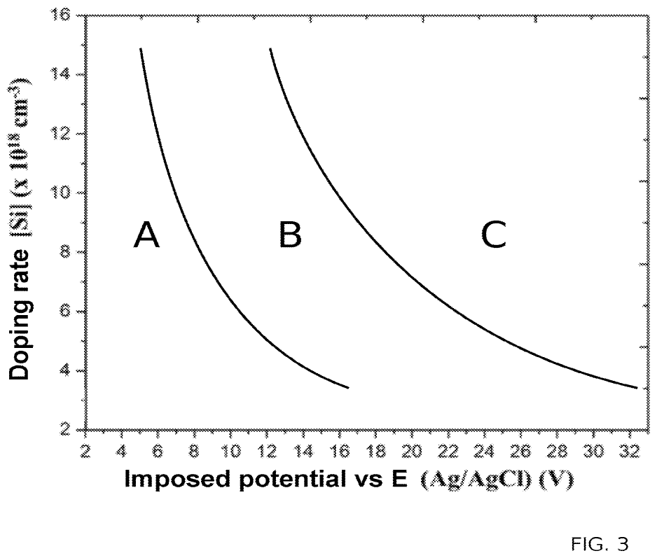

The electro-etching step used in the method according to the present invention is also differentiated from an electro-porosification step, which is carried out in an imposed range of potential and of a doping rate of the different porosified/etched material. FIG. 3 is a schematic graph illustrating the existence of three main operating regions when a study material is immersed in an electrolytic solution and that a potential is imposed between this material and a counterelectrode. The region referenced A on the graph corresponds to pairs of doping rates and of potentials imposed for which the material is not or is very slightly altered. The region A is called pre-porosification or pre-breakdown region. The region B corresponds to conditions in which the material undergoes a porosification during the application of voltage. The region C corresponds to the etching region of the material. The electro-etching step implemented in the method according to the present invention is located in this region C.

According to a first embodiment, the resin layer 20 is preserved during the electro-etching step. The resin layer 20 thus protects the upper face 101 of the pad 100 during the electro-etching. It is this embodiment which is illustrated by the sequencing of FIGS. 1C to 1E. The presence of the resin layer 20 on the pad 100 during the electro-etching makes it possible to prevent that the electro-etching does not remove the material through the upper face 101 of the pad 100. Thus, in this embodiment, the height H₁₀₀₀ of the pillar 1000 is equal to the height H₁₀₀ of the pad 100. The resin layer 20 is preferably removed after the electro-etching (FIG. 1E). Instead of the resin layer 20 or combined with it, it is also possible to use a hard mask made of dielectric material (e.g. SiO₂) to protect the upper face 101 of the pad 100 during the electro-etching step. It is possible that an upper portion of the pad 100, extending preferably from its upper face 101, is very slightly, even non-doped, in order to limit the impact of the electro-etching in this region.

According to another embodiment not illustrated, the resin layer 20 is removed before the electro-etching step. In this embodiment, the electro-etching makes it possible to give the pillar 1000 a height H₁₀₀₀ less than the height H₁₀₀ of the pad 100. This can be desired in certain application where the height dimension must be very small.

In the particular embodiment where a hard mask 30 has been deposited on the substrate 10 before the resin layer 20, the hard mask 30 is not electro-etched during this step. Thus, the assembly illustrated in FIG. 6C is obtained. The hard mask 30 has preserved its characteristic dimension L₁₀₀ while the underlying pillar 1000 has a characteristic dimension L₁₀₀₀, less than L₁₀₀. Thus, the hard mask 30 extends below the underlying pillar 1000 projecting into the main plane XY.

The method according to the invention has, until now, been presented for one single pad 100, then one single pillar 1000, but it is understood that it can be implemented to manufacture a plurality of pillars 1000.

As indicated above, the substrate 10 can be doped. The doping of the substrate 10 can, in particular, be configured as a function of the dimensions and of the shape desired for the pillars 1000.

Advantageously, the doping of the substrate 10 is not uniform.

First, the doping of the substrate 10 can vary along the third direction Z. In particular, the substrate 10 can be a bilayer and comprise a first layer 15 having a doping D₁ and a second layer 16 having a doping D₀. The etching step is thus advantageously configured such that the etching stops at the interface between the first layer 15 and the second layer 16. The pad 100 is thus formed by the first layer 15 (see FIG. 1C). By giving a doping D₁ to the first layer 15 greater than the doping D₀ of the second layer 16, it is ensured that the electro-etching is concentrated on the pad 100. Advantageously, the doping D₀ is chosen such that the second layer 16 is very slightly etched, even is not etched at all, during the electro-etching step.

In particular, the dopings D₁ and D₀ can be chosen from an “abacus” such as that illustrated in FIG. 3. Such an “abacus” makes it possible to define the respective doping rates such that at a given potential, there is a selectivity between the first layer, highly doped, and the second layer, lowly doped. For a given potential:
the doping rate of the second layer 16 must preferably be located in the region A or optionally in the zone B such that the second layer 16 is not electro-etched during the electro-etching step. In the case where the doping rate of the second layer 16 is located in the region B, a protective layer can optionally be deposited on the second layer 16, between the pillars, to avoid it being porosified during the electro-etching step.
the doping rate of the first layer 15 must be located in the region C such that the first layer 15 is etched during the electro-etching step.

For example, by fixing the potential at 15V, a doping rate D₀ of the first layer 15 can be fixed greater than or equal to 1.2^{e}19 at/cm³ and a doping rate D₁ of the second layer 16 can be fixed less than or equal to 3^{e}18 at/cm³.

The substrate 10 can also be a trilayer. A third layer can moreover be inserted between the first layer 15 and the second layer 16. The third layer is preferably slightly or not doped. Its doping is thus preferably strictly less than D₀ and than D₁. The third layer has, for example, a doping less than 5.10¹⁷at/cm³. The presence of this third slightly or not doped layer makes it possible to limit, even avoid the etching of the second layer 16 which conducts the electrons.

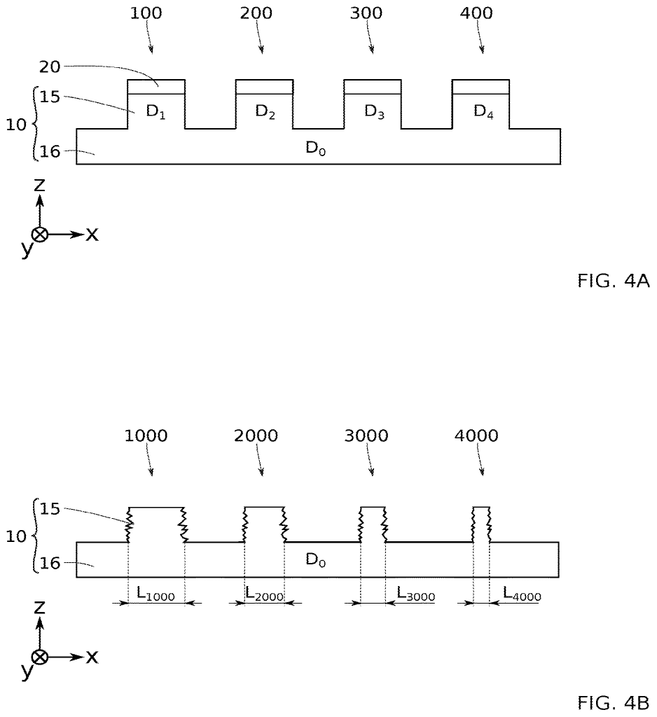

Moreover, the doping of the substrate 10 can vary along the first and second directions X, Y. In particular, the doping of the substrate 10 can be configured such that after the step of etching and of forming the pads, at least some of these pads have distinct dopings. For example, FIG. 4A illustrates an assembly of four pads 100, 200, 300, 400, each having a distinct doping D₁, D₂, D₃, D₄, with D₁<D₂<D₃<D₄. During the electro-etching step, at a given potential, the more a pad is doped, the more this is etched. Thus, the pillars 1000, 2000, 3000, 4000 obtained after the electro-etching step (FIG. 4B) have distinct characteristic dimensions, in this case, decreasing: L₁₀₀₀<L₂₀₀₀<L₃₀₀₀<L₄₀₀₀.

It is moreover possible that certain zones of the substrate 10 have no doping. The pads formed in these zones will therefore not be etched during the electro-etching step (in this case, L₁₀₀=L₁₀₀₀).

Thus, by performing a non-uniform doping of the substrate 10 in the main plane XY, it is possible to form structures of different sizes. This makes it possible to have a large number of degrees of freedom on the sizing of the final microstructures and to multiply the geometries accessible on one same substrate, with the option of making very small structures coexist with a lot larger structures. Thanks to the method according to the invention, it is, for example, possible to form on one same substrate, structures of ten nanometres and structures of a few hundred nanometres.

The different doping levels within the substrate 10 can be obtained by different methods.

The substrate 10 can, in particular, be implanted, for example with silicon (Si(n)) or with magnesium (Mg(p)). It is, in particular, possible to perform an inhomogeneous implantation to give the future pads 100, 200, 300, 400 distinct doping rates.

Doping by implantation can be replaced by a metal organic chemical vapour deposition (MOCVD) doping, with Si or Ge as the dopant, in particular. It is, for example, possible to carry out two successive epitaxy steps with successive maskings to obtain two different doping levels, in order to form the bilayer 15, 16 of the substrate 10.

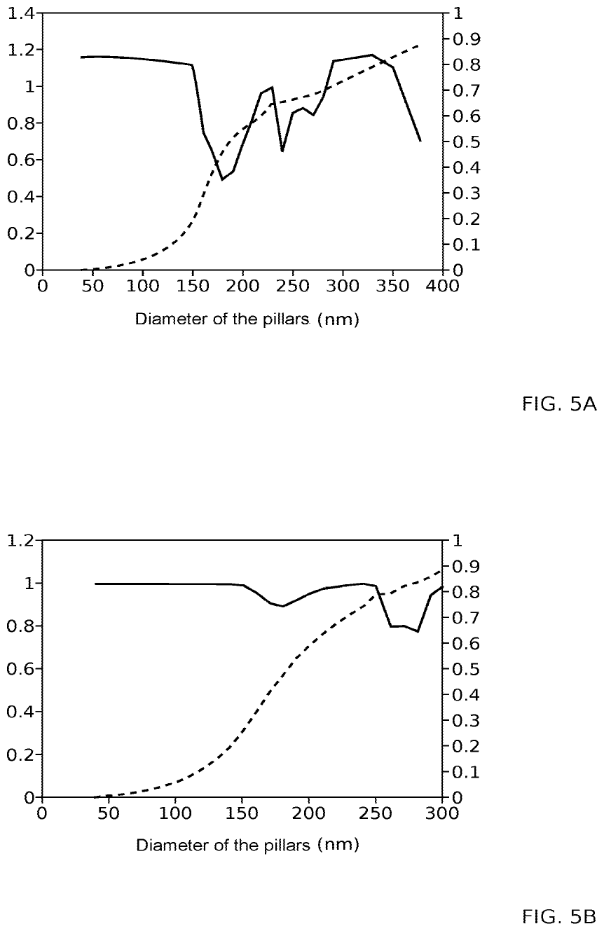

As mentioned above, the present invention has, as a particularly advantageous application, the field of metasurfaces formed from an assembly of very small structures. FIGS. 5A and 5B illustrate the interest of the invention in this field.

FIGS. 5A and 5B are results of simulations illustrating the transmission and the phase shift of a metasurface as a function of the diameter of the structures forming it. The graph of FIG. 5A has been obtained for a period of 420 nm between the structures and FIG. 5B for a period of 340 nm. In particular, significant drops in transmission are observed in FIG. 5A. These low transmission values illustrate a problem of resonances on certain geometries, i.e. in particular for certain period/diameter pairs. To manufacture a good quality metasurface, domains where transmission is high must be found. It appears that this is the case for small diameter values. The surrounded zone in FIG. 5B corresponds, for example, to diameter values which, for a period of 340 nm, give very good results. These are diameters of between 40 and 100 nm. Therefore, the interest of the invention is understood in this particular field.

Regarding the different embodiments described above, it appears that the present invention makes it possible, by combining techniques coming from two different fields, to manufacture very small structures. The present invention moreover makes it possible to simultaneously form structures of distinct dimensions, and even structures, the dimensions of which are of different magnitudes.

The present invention is not limited to the manufacture of structures for optical metasurfaces. It can also be used in manufacturing any optoelectronic or microelectronic device requiring small dimensions, like for example, a diode or a lens.

The invention is not limited to the embodiments described above, and extends to all the embodiments covered by the invention.

1-14. (canceled)

15. A method for manufacturing microstructures, comprising:
providing a substrate having an upper face extending parallel to a main plane;
anisotropically etching the substrate from the upper face along a vertical direction perpendicular to the main plane to form at least one pad in the substrate, the at least one pad having a first surface projected onto the main plane and a height along the vertical direction; and
electro-etching the at least one pad to form a pillar, the pillar having a second surface projected onto the main plane that is smaller than the first surface, and a height along the vertical direction equal to the height of the pad.

16. The method of claim 15, wherein the second surface is less than or equal to 0.75 times the first surface.

17. The method of claim 15, wherein the at least one pad has a characteristic dimension projected onto the main plane that is greater than or equal to 80 nm.

18. The method of claim 17, wherein the characteristic dimension of the at least one pad is less than or equal to 1 μm.

19. The method of claim 15, wherein the pillar has a characteristic dimension projected onto the main plane that is less than or equal to 50 nm.

20. The method of claim 15, wherein the at least one pad has a first characteristic dimension projected onto the main plane and the pillar has a second characteristic dimension projected onto the main plane, and wherein the second characteristic dimension is less than or equal to 0.75 times the first characteristic dimension.

21. The method of claim 15, wherein:
the substrate has non-uniform doping;
the anisotropic etching forms a plurality of pads including a first pad and a second pad formed in regions of the substrate having different dopings; and
the electro-etching forms a first pillar from the first pad and a second pillar from the second pad, the first pillar and the second pillar having different second surfaces projected onto the main plane.

22. The method of claim 15, wherein the substrate includes a non-doped region and a doped region, and the anisotropic etching forms a plurality of pads including a first pad formed in the non-doped region and a second pad formed in the doped region.

23. The method of claim 15, wherein the anisotropic etching comprises forming a mask on the upper face of the substrate, the mask comprising openings, and wherein the electro-etching is performed in the presence of the mask.

24. The method of claim 15, wherein the anisotropic etching comprises forming a mask on the upper face of the substrate, the mask comprising openings, and wherein the electro-etching is performed after removing the mask.

25. The method of claim 23, wherein:
the anisotropic etching further comprises forming a hard mask on the upper face of the substrate prior to forming the mask;
the mask is formed on the hard mask;
the anisotropic etching etches the hard mask such that the hard mask has a surface projected onto the main plane equal to the first surface; and
the hard mask preserves the surface during the electro-etching.

26. The method of claim 15, wherein the substrate comprises a semiconductor material including one of Ge, Si, InP, GaN, InGaN, or AlGaN.

27. A method for manufacturing a microelectronic component, comprising performing the method of claim 15, wherein the pillar forms a diode.

28. A method for manufacturing a microelectronic component, comprising performing the method of claim 15, wherein the pillar forms an optical element including one of an extraction structure, an optical metasurface, a photonic crystal, or a diffractive element.
